(19) United States
(12) Patent Application Publication
(10) Pub. No.: US 2025/0362567 A1
(43) Pub. Date: Nov. 27, 2025

(54) OPTICAL SUBSTRATE AND SOLID STATE IMAGING DEVICE PACKAGE

(71) Applicant: KANEKA CORPORATION, Osaka (JP)

(72) Inventors: Makoto Kutsumizu, Osaka (JP); Daiki Kinoshita, Osaka (JP)

(73) Assignee: KANEKA CORPORATION, Osaka (JP)

(21) Appl. No.: 19/290,855

(22) Filed: Aug. 5, 2025

Related U.S. Application Data
(63) Continuation of application No. PCT/JP2024/001577, filed on Jan. 22, 2024.

(30) Foreign Application Priority Data
Feb. 8, 2023 (JP) 2023-017388

(51) Int. Cl. G03B 11/04

(52) U.S. Cl. CPC G03B 11/045

(57) ABSTRACT

An optical substrate can reduce noise in a captured image of a solid state imaging device package. The optical substrate includes a transparent substrate and a light-shielding film that is formed from a photo-curable resin composition including a colorant. The light-shielding film is stacked on one principal surface of the transparent substrate, and has a light path opening. The skewness Ssk of a surface of the light-shielding film on the side opposite the transparent substrate is a negative value.

### TECHNICAL FIELD

One or more embodiments of the present invention relate to an optical substrate and a solid-state imaging device package.

### BACKGROUND

A solid-state imaging device package is widely used in which a frame surrounding at least a functional unit (sensor region) of a solid-state imaging device is directly bonded to the solid-state imaging device or bonded to a substrate on which the solid-state imaging device is mounted, and an opening of the frame is covered with a transparent substrate (optical substrate) such as glass. In such a solid-state imaging device package, it is known that by providing a light-shielding material in a peripheral region of the transparent substrate that does not face the functional unit of the solid-state imaging device, unintended light is suppressed from being reflected inside the solid-state imaging device package and being incident on the functional unit (for example, see Patent Document 1). By providing such a light-shielding material, it is possible to reduce noise, such as flare and ghosting, in a captured image.

### Patent Document

Patent Document 1: U.S. Pat. No. 10,312,276, Specification

Demands for size reduction and higher definition of solid-state imaging device packages are increasing day by day, and light-shielding materials are also required to have high precision. Therefore, it is conceivable to form a black resin pattern on the transparent substrate in advance by using a technique such as printing or photolithography. However, when a black resin is laminated on the glass plate, there is a risk that a pigment or the like contained in the black resin adheres to a region serving as an optical path of the transparent substrate, thus deteriorating image quality. Therefore, one or more embodiments of the present invention are to provide an optical substrate capable of reducing noise in an image captured by a solid-state imaging device package and a solid-state imaging device package in which noise in a captured image is small.

### SUMMARY

An optical substrate according to one aspect of one or more embodiments of the present invention includes a transparent substrate; and a light-shielding film formed from a photocurable resin composition containing a coloring agent, laminated on one principal surface of the transparent substrate, and having an optical path opening. A surface of the light-shielding film on a side opposite the transparent substrate has a skewness Ssk of a negative value.

In the optical substrate, a content of the coloring agent in the light-shielding film may be 8 mass % or less.

In the optical substrate, the surface of the light-shielding film on the side opposite the transparent substrate may have an arithmetic average roughness Ra of 50 nm or more and 3000 nm or less.

The optical substrate may further include a frame disposed on an opposite side of the light-shielding film from the transparent substrate, the frame having an inner diameter larger than the optical path opening.

A solid-state imaging device package according to one aspect of one or more embodiments of the present invention includes the above-described optical substrate; and a solid-state imaging device that captures an image of light incident through the transparent substrate and the optical path opening.

### Effects of the Invention

According to one or more embodiments of the present invention, noise in an image captured by a solid-state imaging device package can be reduced.

### BRIEF DESCRIPTION OF THE DRAWINGS

FIG. 1 is a cross-sectional view of a solid-state imaging device package according to one or more embodiments of the present invention; and

FIG. 2 is a cross-sectional view of a solid-state imaging device package according to one or more embodiments of the present invention.

### DETAILED DESCRIPTION

Hereinafter, one or more embodiments of the present invention will be described with reference to the drawings. The same components in a later-described embodiment as those in an earlier-described embodiment are denoted by the same reference numerals, and redundant descriptions thereof may be omitted. The drawings have been adjusted in proportion and some details have been omitted to make the features easier to understand.

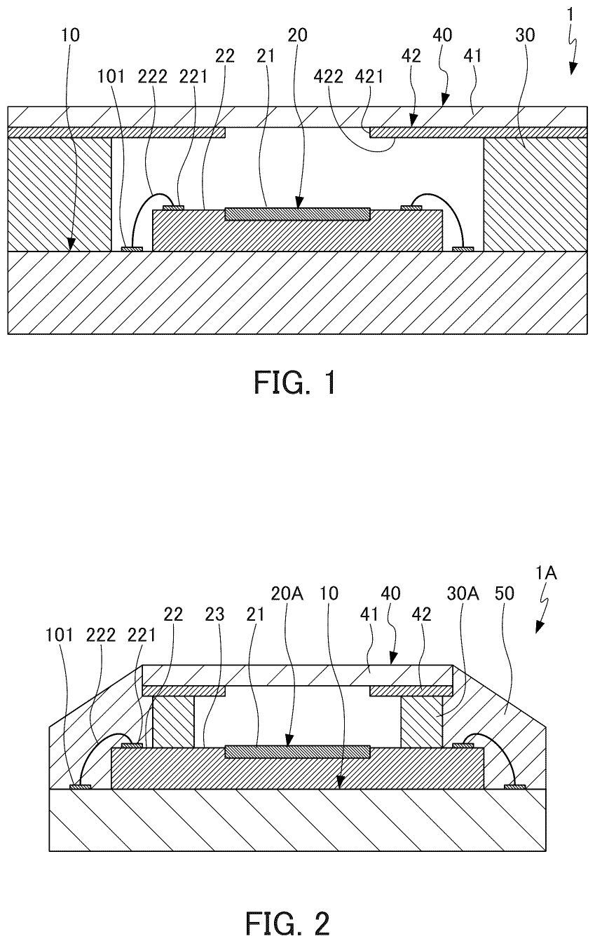

FIG. 1 is a cross-sectional view of a solid-state imaging device package 1 according to one or more embodiments of the present invention. The solid-state imaging device package 1 includes a mounting substrate 10, a solid-state imaging device 20 mounted on the mounting substrate 10, a frame 30 bonded to the mounting substrate 10 and surrounding the solid-state imaging device 20, and an optical substrate 40 bonded to the frame 30 and covering the solid-state imaging device 20.

The mounting substrate 10 is a structural member that supports the solid-state imaging device 20 and the frame 30. Therefore, the mounting substrate 10 is formed from a material having sufficient rigidity. The mounting substrate 10 may be a simple support, but may be a circuit board on which a circuit for supplying power to the solid-state imaging device 20 and extracting a signal from the solid-state imaging device 20 is formed. In one or more embodiments, the mounting substrate 10 has a circuit including an electrode 101 for electrically connecting to the solid-state imaging device 20.

Examples of the mounting substrate 10 include organic materials such as polyimide, polyester, ceramic, epoxy, bismaleimide triazine, and phenol resin; structures in which paper, a glass fiber nonwoven fabric, or the like is impregnated with the organic materials and then heated and cured; ceramics such as alumina, aluminum nitride, beryllium oxide, and silicon nitride; and metal substrates. Among them, a glass epoxy substrate and a ceramic substrate are preferable. A circuit having a metal wiring pattern or a metal bump can be formed on the surface or inside of each of these insulating substrates.

The solid-state imaging device 20 is mounted on the side of the mounting substrate 10 facing the optical substrate 40. The solid-state imaging device 20 is formed on a surface facing the optical substrate 40, and includes a functional unit 21 that performs imaging and a connection unit 22 for performing electrical connection. The solid-state imaging device 20 is mounted such that the imaging surface of the functional unit 21 is parallel to the principal surface of the mounting substrate 10, that is, such that the optical axis is parallel to the normal direction of the mounting substrate 10. As the solid-state imaging device 20, for example, a two-dimensional imaging device such as a CMOS image sensor may be used. As the functional unit 21, for example, a two-dimensional imaging device structure such as a CMOS image sensor may be formed. The connection unit 22 is a region in which an electrode 221, etc. for electrically connecting the solid-state imaging device 20 to the mounting substrate 10, etc. is disposed. The connection unit 22 may be provided outside the functional unit 21 as in one or more embodiments. Alternatively, the connection unit 22 may be provided on the surface opposite the functional unit 21, i.e., on the surface facing the mounting substrate 10. In one or more embodiments, the electrodes 221 of the solid-state imaging device 20 and the electrodes 101 of the mounting substrate 10 are electrically connected to each other by wires 222.

The frame 30, together with the mounting substrate 10 and the optical substrate 40, forms a sealed space that encloses the solid-state imaging device 20. The frame 30 may be formed from a colored material, that is, a resin composition containing a coloring agent so as to prevent light from being incident on the functional unit 21 of the solid-state imaging device 20 from the side. The frame 30 may have a light diffusion structure so as to suppress the amount of light incident on the functional unit 21 of the solid-state imaging device 20 from the side by diffusing the incident light. Examples of the light diffusion structure include an irregular surface structure and a structure containing a light diffusion material therein.

The frame 30 may be formed from a thermosetting resin having heat resistance. Preferable examples of the thermosetting resin include epoxy resins, silicon resins (addition type silicone resins, condensation type silicone resins, and siloxane bond-containing curable resins), urethane resins, polyimide resins, acrylate resins, unsaturated polyester resins, and phenol resins. The frame 30 may be bonded to the mounting substrate 10 with an adhesive, or may be molded on the mounting substrate 10. Alternatively, the frame 30 may be formed integrally with the mounting substrate 10 by, for example, a ceramic material or the like.

The optical substrate 40 allows light to be incident on the mounting substrate 10. The optical substrate 40 is itself the optical substrate according to one or more embodiments of the present invention. The optical substrate 40 includes a transparent substrate 41 and a light-shielding film 42 laminated on a principal surface of the transparent substrate 41. The optical substrate 40 may be bonded to the frame 30 with an adhesive, or may be directly molded on the optical substrate 40. The light-shielding film 42 of the optical substrate 40 and the frame 30 may be integrally molded.

The transparent substrate 41 is a transparent plate material. The transparent substrate 41 can be formed from a transparent ceramic such as glass or sapphire, or a transparent plastic such as an acrylic resin or polycarbonate, and may be formed from a transparent ceramic from the viewpoint of reliability, and may be formed from glass from the viewpoint of versatility. The type of glass forming the transparent substrate 41 is not particularly limited, and examples thereof include quartz glass, borosilicate glass, and alkali-free glass.

The light-shielding film 42 has an optical path opening 421 that defines an optical path through which light from a subject passes and is then incident on the functional unit 21 of the solid-state imaging device 20. That is, the solid-state imaging device 20 captures an image of light incident through the transparent substrate 41 and the optical path opening 421. In the light-shielding film 42, an irregularity structure that scatters light is formed on a light diffusion surface 422 that is a surface on the side opposite the transparent substrate 41. The light-shielding film 42 may be formed on one principal surface of the transparent substrate 41, but may be formed on a surface of the optical substrate 40 facing the solid-state imaging device 20 in order to suppress not only light from entering the internal space of the solid-state imaging device package 1 from the outside but also light that is reflected inside the solid-state imaging device package 1 from being re-reflected by the optical substrate 40 and being incident on the functional unit 21 of the solid-state imaging device 20. The light-shielding film 42 may be formed so as to overlap the frame 30 so as not to form a path of light reaching the functional unit 21 of the solid-state imaging device 20 on the outer side.

The light-shielding film 42 is formed from a photocurable resin composition containing a coloring agent. The light-shielding film 42 can be formed by any method such as printing. By forming the light-shielding film 42 from a photocurable resin composition, the light-shielding film 42 having a uniform thickness and an accurate planar shape can be formed by a photolithography technique. The photocurable resin composition includes a resin component having a reactive group such as an epoxy group or an acrylic group, and a photopolymerization initiator. Examples of the coloring agent contained in the photocurable resin composition include organic pigments, inorganic pigments, and dyes. From the viewpoint of heat resistance and colorability, a pigment may be used as the coloring agent. When a black colored pattern is formed, a black pigment may be used as the coloring agent. Examples of colored patterns other than the black pattern include a red pattern, a yellow pattern, and a blue pattern.

As the pigment, a pigment that absorbs a wide range of wavelengths in a visible light region is preferable. Among pigments that absorb a wide range of wavelengths in the visible light region, examples of black organic pigments include anthraquinone-based black pigments, perylene-based black pigments, azo-based black pigments, and lactam-based black pigments. Among these, perylene-based black pigments and lactam-based black pigments are preferable because of their excellent light-shielding properties. Examples of black inorganic pigments include carbon black and black low-order titanium oxynitride. Examples of other inorganic pigments include carbon black, composite metal oxide pigments, titanium oxide, barium sulfate, lead sulfate, yellow lead, red iron oxide, azurite, smalt, chromium oxide, antimony white, zinc sulfide, zinc, manganese violet, cobalt violet, and magnesium carbonate. Examples of the dye include azo-based compounds, anthraquinone-based compounds, perylene-based compounds, perinone-based compounds, phthalocyanine-based compounds, carbonium-based compounds, and indigoid-based compounds.

Examples of pigments used to obtain colored patterns other than black patterns include chromatic pigments such as red, orange, yellow, green, blue, violet, cyanine, and magenta.

Specific examples of the chromatic pigments include color index (C.I.) pigment yellow 1, 10, 83, etc.; C.I. pigment orange 2, 5, 13, etc.; C.I. pigment red 1, 2, 3, etc.; C.I. pigment green 7, 10, 36, etc.; and C.I. pigment blue 1, 2, 15, etc. These pigments may be used alone or in various combinations.

The lower limit of the content of the coloring agent in the photocurable resin composition forming the light-shielding film 42 may be 0.5 mass %, 1.0 mass %, or 1.5 mass %. The upper limit of the content of the coloring agent in the photocurable resin composition forming the light-shielding film 42 may be 8 mass %, 6 mass %, or 4 mass %. By setting the content of the coloring agent to be equal to or greater than the lower limit, the light transmittance of the light-shielding film 42 can be sufficiently reduced, and thus flare and ghosting can be effectively suppressed. By setting the content of the coloring agent to be equal to or less than the upper limit, it is possible to suppress the coloring agent from remaining on the surface of the transparent substrate 41 after the photocurable resin composition in the region not irradiated with light is removed.

It is preferable that the optical path opening 421 be a minimum opening necessary for allowing light to be incident on the functional unit 21 of the solid-state imaging device 20. Therefore, the light-shielding film 42 can be formed to extend inward from the top of the frame 30. Conversely, the frame 30 may have an inner diameter larger than the optical path opening 421.

The light diffusion surface 422 reduces the intensity of unintended light incident on the functional unit 21 of the solid-state imaging device 20 by diffusing light, and suppresses perceivable flare and ghosting by increasing the S/N ratio. In particular, since the light-shielding film 42 scatters the transmitted light on the light diffusion surface 422 even when the content of the coloring agent is lowered as described above, image noise can be sufficiently suppressed. Additionally, when unintended light entering the internal space of the solid-state imaging device package 1, such as light obliquely entering the optical path opening 421, is reflected and incident on the light-shielding film 42, the light diffusion surface 422 also suppresses image noise by diffusing light that could be re-reflected by the light-shielding film 42 and be incident on the functional unit 21 of the solid-state imaging device 20.

The irregularity structure of the light diffusion surface 422 can be formed, for example, by embossing, in which a mold having an irregular surface is pressed against the light-shielding film 42 in a semi-cured state (B stage). If the light-shielding film 42 is cured in a state in which the frame 30 is in close contact with the light-shielding film 42 in a semi-cured state in which the light diffusion surface 422 is formed, the optical substrate 40 can be bonded to the frame 30 without using an adhesive.

The skewness Ssk (ISO-25178) of the light diffusion surface 422 may be a negative value. Accordingly, regular reflection can be efficiently reduced, and flare and ghosting can be effectively suppressed. The skewness (Ssk) indicates the symmetry of the height distribution with respect to the average surface of the irregular surface. When the skewness Ssk is 0, the height distribution is vertically symmetrical (the peaks and the valleys are substantially the same, and symmetrical with respect to the average surface). When the skewness Ssk is a negative value, the surface has many fine valleys (biased to the upper side with respect to the average surface), and when the skewness Ssk is a positive value, the surface has many fine peaks (biased to the lower side with respect to the average surface). Therefore, by adopting a structure in which the light diffusion surface 422 has many valleys in which the skewness Ssk is a negative value, the light incident on the light diffusion surface 422 is not only repeatedly reflected at the valleys and attenuated every reflection, but also is reflected so as to be dispersed in multiple directions, reducing regular reflection, so that ghosting and flare can be suppressed.

The lower limit of the skewness Ssk of the light diffusion surface 422 may be −0.80 or −0.70, and the upper limit of the skewness Ssk of the light diffusion surface 422 may be −0.10 or −0.20. By setting the skewness Ssk to be equal to or greater than the lower limit, it becomes easy to make the irregularities finer, and thus flare and ghosting can be more efficiently suppressed. In addition, by setting the skewness Ssk to be equal to or less than the upper limit, regular reflection can be effectively suppressed, and thus flare and ghosting can be reliably suppressed.

The lower limit of the arithmetic mean roughness Ra (JIS-B0601) of the light diffusion surface 422 may be 50 nm, 100 nm, or 200 nm. The upper limit of the arithmetic mean roughness Ra of the light diffusion surface 422 may be 3000 nm, 2800 nm, 2600 nm, 2000 nm, or 1000 nm. By setting the arithmetic average roughness Ra of the light diffusion surface 422 to be equal to or greater than the lower limit, regular reflection can be more effectively suppressed, and thus flare and ghosting can be more efficiently suppressed. In addition, by setting the arithmetic average roughness Ra of the light diffusion surface 422 to be equal to or less than the upper limit, manufacturing becomes relatively easy, and thus manufacturing cost can be suppressed.

The lower limit of the average length RSm (JIS-B0601) of the roughness curve element of the light diffusion surface 422 may be 100 nm, 200 nm, or 300 nm. The upper limit of the average length RSm of the roughness curve element of the light diffusion surface 422 may be 20000 nm, 10000 nm, or 8000 nm. By setting the average length RSm of the roughness curve element of the light diffusion surface 422 to be equal to or greater than the lower limit, manufacturing becomes relatively easy, and thus manufacturing cost can be suppressed. In addition, by setting the average length RSm of the roughness curve element of the light diffusion surface 422 to be equal to or less than the upper limit, regular reflection can be more effectively suppressed, and thus flare and ghosting can be more efficiently suppressed.

Since the solid-state imaging device package 1 having the above-described configuration includes the optical substrate 40 having the light-shielding film 42 capable of suppressing flare and ghosting by the light diffusion surface 422 even when the content of the coloring agent is lowered, foreign matter on the surface of the transparent substrate 41 in the optical path opening 421 can be suppressed, and thus a high-quality image with little noise can be captured.

FIG. 2 is a cross-sectional view of a solid-state imaging device package 1A according to one or more embodiments of the present invention. The solid-state imaging device package 1A includes a mounting substrate 10, a solid-state imaging device 20A mounted on the mounting substrate 10, a frame 30A bonded to the solid-state imaging device 20A, an optical substrate 40 bonded to the frame 30A and covering the solid-state imaging device 20, and a sealing material 50 sealing the outside of the frame 30A and the optical substrate 40 on the mounting substrate 10.

The solid-state imaging device 20A includes a functional unit 21 that performs imaging, a connection unit 22 for performing electrical connection, and a margin unit 23 to which the frame 30A is bonded between the functional unit 21 and the connection unit 22.

The frame 30A is the same as the frame 30 of FIG. 1 except that it is bonded to the margin unit 23 of the solid-state imaging device 20A.

The sealing material 50 seals the outside of the solid-state imaging device 20A, the frame 30, and the optical substrate 40 on the mounting substrate 10, thereby preventing the frame 30 and the optical substrate 40 from being peeled off from the solid-state imaging device 20A by an external object. In addition, the sealing material 50 protects a wire 222 and secures electrical connection between the mounting substrate 10 and the solid-state imaging device 20A.

As the sealing material 50, for example, a thermosetting resin such as an epoxy resin, an acrylic resin, or a silicone resin is preferable, and an epoxy resin is particularly preferable from the viewpoint of toughness and heat resistance. The sealing material 50 may be formed from a resin composition containing a coloring agent or a light diffusing material so as to prevent unintended light from being incident on the functional unit 21. The sealing material 50 may contain a filler such as silica so as to have thixotropy before curing in order to facilitate formation.

Although one or more embodiments of the present invention have been described above, the present invention is not limited to the above-described embodiments, and various changes and modifications can be made. As an example, the solid-state imaging device package according to one or more embodiments of the present invention may be a so-called Chip Size Package in which the planar dimensions of the whole and the optical substrate are substantially equal to those of the solid-state imaging device.

### Examples

Hereinafter, one or more embodiments of the present invention will be specifically described based on Examples, but the present invention is not limited to the following Examples.

Test samples of a solid-state imaging device package having the structure of FIG. 2 were fabricated, and their performances were evaluated. Specifically, a photocurable resin composition for forming a light-shielding film was prepared, coated on a glass substrate, and a light-shielding film in a semi-cured state was formed by photolithography. Various types of optical substrates having light diffusion surfaces having differently shaped irregularities were prepared by embossing, in which various types of molds having differently shaped irregularities on the surface are pressed against the light-shielding film in the semi-cured state. These optical substrates were each bonded to a frame bonded in advance to a mounting substrate on which a solid-state imaging device is mounted, whereby test samples 1 to 15 of the solid-state imaging device package were fabricated. Note that test sample 15 was not embossed.

In the preparation of the photocurable resin composition, first, 143 μL of a xylene solution (“Pt-VTSC-3X” manufactured by Umicore Precious Metals Japan, solution containing 3 mass % of platinum) of a platinum vinylsiloxane complex was added to a mixture of 40 g of diallyl isocyanurate, 29 g of diallyl monomethyl isocyanurate, and 264 g of 1,4-dioxane to obtain a solution S1. Separately, 88 g of 1,3,5,7-tetrahydrogen-1,3,5,7-tetramethylcyclotetrasiloxane was dissolved in 176 g of toluene to obtain a solution S2.

Then, in a nitrogen atmosphere containing 3 volumes of oxygen, in a state where the solution S2 was heated to a temperature of 105° C., the solution S1 was dropped into the solution S2 over a period of 3 hours, and after completion of the dropping, stirring was performed for 30 minutes while maintaining the temperature of 105° C. to obtain a solution S3. Separately, 62 g of 1-vinyl-3,4-epoxycyclohexane was dissolved in 62 g of toluene to obtain a solution S4. Then, in a nitrogen atmosphere containing 3 volumes of oxygen, in a state where the solution S3 was heated to a temperature of 105° C., the solution S4 was dropped into the solution S3 over 1 hour, and after completion of the dropping, stirring was performed for 30 minutes while maintaining the temperature of 105° C. to obtain a solution S5.

After the solution S5 was cooled, the solvents (toluene, xylene, and 1,4-dioxane) were distilled off from the solution S5 under reduced pressure to obtain a solid content. Next, 49 parts by mass of propylene glycol 1-monomethyl ether 2-acetate, 15 parts by mass of an epoxy monomer (3′,4′-epoxycyclohexylmethyl 3,4-epoxycyclohexanecarboxylate: “Celloxide 2021P” manufactured by Daicel Corporation), 1 part by mass of a sulfonium salt-based photocationic polymerization initiator (“CPI-210S” manufactured by San-Apro Ltd.), and 3 to 15 parts by mass of a black pigment (carbon black: “MA-100” manufactured by Mitsubishi Chemical Corporation) (see Table 1) were added to 100 parts by mass of the obtained solid content to obtain a photocurable resin composition for forming a light-shielding film.

The arithmetic mean roughness Ra (evaluation length: 20 μm) and skewness Ssk of the light diffusion surface of the light-shielding film formed on the glass substrate were measured using a 3D measuring laser microscope “LEXT-OLS5100” manufactured by Olympus Corporation. The skewness Ssk was obtained by randomly selecting 10 measurement points (square regions of 20 μm×20 μm) and averaging the measured values of the skewness Ssk at the selected measurement points (see Table 1).

The performance of the solid-state imaging device package was evaluated by the number of residues on the transparent substrate inside the optical path opening and the ghosting index of the photographed image. With respect to the number of residues, a range of 1 mm square of the transparent substrate was observed using a 3D measuring laser microscope “LEXT-OLS4000” manufactured by Olympus Corporation. When there were 10 or more residues or foreign matters of 10 μm or more, it was evaluated as D, when there were 6 to 9 residues or foreign matters, it was evaluated as C, when there were 3 to 5 residues or foreign matters, it was evaluated as B, and when there were 2 or less residues, it was evaluated as A. The ghosting index was calculated by using a ghosting flare evaluation system “GCS-2T” manufactured by Tsubosaka Electric Co., Ltd. to determine the number of abnormal pixels exceeding a predetermined threshold ( 1/100 million of the brightness of the light source), then dividing the number of abnormal pixels by the total number of pixels (number of abnormal pixels/total number of pixels), and finally expressing this value as a percentage relative to test sample 15 that was not embossed (see Table 1).

TABLE 1

| Test | Pigment | | | | |
|---|---|---|---|---|---|
| sample | [parts by | Ra | | | Ghosting |
| number | mass] | [nm] | Ssk | Residue | Index |
| 1 | 3 | 100 | −0.22 | A | 85 |
| 2 | 3 | 200 | −0.22 | A | 81 |
| 3 | 3 | 350 | −0.51 | A | 70 |
| 4 | 3 | 450 | −0.35 | A | 65 |
| 5 | 3 | 500 | −0.32 | A | 62 |
| 6 | 3 | 850 | −0.45 | A | 71 |
| 7 | 3 | 1000 | −0.44 | A | 85 |
| 8 | 3 | 1500 | −0.45 | A | 89 |
| 9 | 3 | 2500 | −0.44 | A | 90 |
| 10 | 5 | 450 | −0.35 | A | 65 |
| 11 | 8 | 450 | −0.35 | B | 64 |
| 12 | 10 | 450 | −0.35 | C | 65 |
| 13 | 3 | 3000 | 0.55 | A | 95 |
| 14 | 15 | 211 | 0.3 | D | 80 |
| 15 | 3 | 30 | 0.02 | A | 100 |

As described above, it was confirmed that, by setting the skewness Ssk to a negative value, the ghosting index can be sufficiently reduced by the addition of a relatively small amount of pigment, thus suppressing residues in the optical path.

### EXPLANATION OF REFERENCE NUMERALS

1, 1A solid-state imaging device package
10 mounting substrate
20, 20A solid-state imaging device
21 functional unit
22 connection unit
23 margin unit
30, 30A frame
40 optical substrate
41 transparent substrate
42 light-shielding film
421 optical path opening
422 light diffusion surface
50 sealing material

Although the disclosure has been described with respect to only a limited number of embodiments, those skilled in the art, having benefit of this disclosure, will appreciate that various other embodiments may be devised without departing from the scope of the present disclosure. Accordingly, the scope of the invention should be limited only by the attached claims.

1. An optical substrate comprising:
a transparent substrate; and
a light-shielding film formed from a photocurable resin composition containing a coloring agent, laminated on one principal surface of the transparent substrate, and having an optical path opening,
wherein a surface of the light-shielding film on a side opposite the transparent substrate has a skewness Ssk of a negative value.

2. The optical substrate according to claim 1, wherein a content of the coloring agent in the light-shielding film is 8 mass % or less.

3. The optical substrate according to claim 1, wherein the surface of the light-shielding film on the side opposite the transparent substrate has an arithmetic average roughness Ra of 50 nm or more and 3000 nm or less.

4. The optical substrate according to claim 1, further comprising a frame disposed on an opposite side of the light-shielding film from the transparent substrate, the frame having an inner diameter larger than the optical path opening.

5. A solid-state imaging device package comprising:
the optical substrate according to claim 1; and
a solid-state imaging device that captures an image of light incident through the transparent substrate and the optical path opening.
